(19) United States
(12) Patent Application Publication
(10) Pub. No.: US 2024/0088277 A1
(43) Pub. Date: Mar. 14, 2024

(54) FIELD EFFECT TRANSISTOR WITH CHANNEL CAPPING LAYER

(71) Applicant: International Business Machines Corporation, Armonk, NY (US)

(72) Inventors: Ruqiang Bao, Niskayuna, NY (US); Brent A. Anderson, Jericho, VT (US); Curtis S. Durfee, Schenectady, NY (US); Gen Tsutsui, Glenmont, NY (US); Junli Wang, Slingerlands, NY (US)

(21) Appl. No.: 17/931,982

(22) Filed: Sep. 14, 2022

(51) Int. Cl. H01L 29/775; H01L 21/02; H01L 21/8238; H01L 27/092; H01L 29/06; H01L 29/161; H01L 29/423; H01L 29/66

(52) U.S. Cl. CPC H01L 29/775; H01L 21/02532; H01L 21/02603; H01L 21/823807; H01L 27/092; H01L 29/0673; H01L 29/161; H01L 29/42392; H01L 29/66439; H01L 29/66545; H01L 29/66553

(57) ABSTRACT

A semiconductor device is provided. The semiconductor device includes a semiconductor substrate, and a pFET transistor formed on the semiconductor substrate. The pFET transistor includes a plurality of channel regions. An uppermost channel region of the plurality of channel regions includes an uppermost active semiconductor layer and a capping layer formed on the uppermost active semiconductor layer.

### BACKGROUND

The present disclosure relates to fabrication methods and resulting structures for semiconductor devices. More specifically, the present disclosure relates to fabrication methods and resulting structures for field effect transistors (FETs) with stacked n-type and p-type nanosheets for complementary metal oxide semiconductor (CMOS) technologies.

In certain semiconductor device fabrication processes, many semiconductor devices, such as n-type field effect transistors (nFETs) and p-type field effect transistors (pFETs), may be fabricated on a single wafer. Non-planar transistor device architectures (e.g., fin-type FETs (FinFETs) and nanosheet FETs) can provide increased device density and increased performance over planar transistors. As semiconductor integrated circuits (ICs) and/or chips become smaller, the implementation of stacked nanosheets in semiconductor devices has increased. Nanosheets generally refer to two-dimensional nanostructures with a thickness range on the order of about 1 nanometer (nm) to about 100 nm, and they can facilitate the fabrication of non-planar semiconductor devices having a reduced footprint compared to conventional planar-type semiconductor devices. For example, nanosheet transistors, in contrast to conventional planar FETs, include a gate stack that wraps around the full perimeter of multiple stacked nanosheet channel regions for a reduced device footprint and improved control of channel current flow. Nanosheet transistor configurations may enable fuller depletion in the nanosheet channel regions and reduce short-channel effects. Accordingly, nanosheets and nanowires are seen as feasible options for reducing the footprints of semiconductor transistor devices to 7 nanometers or less.

### SUMMARY

Embodiments of the present disclosure relate to a semiconductor device. The semiconductor device includes a semiconductor substrate, and a pFET transistor formed on the semiconductor substrate. The pFET transistor includes a plurality of channel regions. An uppermost channel region of the plurality of channel regions of the pFET transistor includes an uppermost active semiconductor layer and a capping layer formed on the uppermost active semiconductor layer.

Embodiments of the present disclosure relate to a method of manufacturing a semiconductor device. The method includes forming a pFET transistor on a semiconductor substrate. The pFET transistor includes a plurality of channel regions, and an uppermost channel region of the pFET transistor includes an uppermost active semiconductor layer and a capping layer formed on the uppermost active semiconductor layer.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, explain the principles of the disclosure. The drawings are only illustrative of certain embodiments and do not limit the disclosure.

FIG. 1A is a cross-sectional view of a semiconductor device at an intermediate stage of the manufacturing process and taken along the line Y-Y of FIG. 1B, according to embodiments.

FIG. 1B is a top view of the semiconductor device of FIG. 1A, according to embodiments.

FIG. 1C is a cross-sectional view of the semiconductor device FIG. 1A taken along the line X-X of FIG. 1B, according to embodiments.

FIG. 2A is a cross-sectional view of the semiconductor device of FIG. 1A after additional manufacturing operations and taken along the line Y-Y of FIG. 1B, according to embodiments.

FIG. 2B is a cross-sectional view of the semiconductor device FIG. 1C after additional fabrication operations and taken along the line X-X of FIG. 1B, according to embodiments.

FIG. 3A is a cross-sectional view of the semiconductor device of FIG. 2A after additional manufacturing operations and taken along the line Y-Y of FIG. 1B, according to embodiments.

FIG. 3B is a cross-sectional view of the semiconductor device FIG. 2B after additional fabrication operations and taken along the line X-X of FIG. 1B, according to embodiments.

FIG. 4A is a cross-sectional view of the semiconductor device of FIG. 3A after additional manufacturing operations and taken along the line Y-Y of FIG. 1B, according to embodiments.

FIG. 4B is a cross-sectional view of the semiconductor device FIG. 3B after additional fabrication operations and taken along the line X-X of FIG. 1B, according to embodiments.

FIG. 5A is a cross-sectional view of the semiconductor device of FIG. 4A after additional manufacturing operations and taken along the line Y-Y of FIG. 1B, according to embodiments.

FIG. 5B is a cross-sectional view of the semiconductor device FIG. 4B after additional fabrication operations and taken along the line X-X of FIG. 1B, according to embodiments.

FIG. 6A is a cross-sectional view of the semiconductor device of FIG. 5A after additional manufacturing operations and taken along the line Y-Y of FIG. 1B, according to embodiments.

FIG. 6B is a cross-sectional view of the semiconductor device FIG. 5B after additional fabrication operations and taken along the line X-X of FIG. 1B, according to embodiments.

FIG. 7A is a cross-sectional view of the semiconductor device of FIG. 6A after additional manufacturing operations and taken along the line Y-Y of FIG. 1B, according to embodiments.

FIG. 7B is a cross-sectional view of the semiconductor device FIG. 6B after additional fabrication operations and taken along the line X-X of FIG. 1B, according to embodiments.

FIG. 8A is a cross-sectional view of the semiconductor device of FIG. 7A after additional manufacturing operations and taken along the line Y-Y of FIG. 1B, according to embodiments.

FIG. 8B is a cross-sectional view of the semiconductor device FIG. 7B after additional fabrication operations and taken along the line X-X of FIG. 1B, according to embodiments.

FIG. 9A is a cross-sectional view of the semiconductor device of FIG. 8A after additional manufacturing operations and taken along the line Y-Y of FIG. 1B, according to embodiments.

FIG. 9B is a cross-sectional view of the semiconductor device FIG. 8B after additional fabrication operations and taken along the line X-X of FIG. 1B, according to embodiments.

FIG. 10A is a cross-sectional view of the semiconductor device of FIG. 8A after additional manufacturing operations and taken along the line Y-Y of FIG. 9B, according to embodiments.

FIG. 10B is a cross-sectional view of the semiconductor device FIG. 9B after additional fabrication operations and taken along the line X-X of FIG. 1B, according to embodiments.

FIG. 11A is a cross-sectional view of the semiconductor device of FIG. 10A after additional manufacturing operations and taken along the line Y-Y of FIG. 1B, according to embodiments.

FIG. 11B is a cross-sectional view of the semiconductor device FIG. 10B after additional fabrication operations and taken along the line X-X of FIG. 1B, according to embodiments.

### DETAILED DESCRIPTION

The present disclosure describes nanosheet FET devices and methods of manufacturing the FET devices. In particular, the present disclosure describes nanosheet FET devices that include a channel capping layer to improve pFET Vt uniformity and performance. In certain examples, the channel capping layer is a thin SiGe layer that if formed as part of the top channel.

The flowcharts and cross-sectional diagrams in the Figures illustrate methods of manufacturing nanosheet FET devices according to various embodiments. In some alternative implementations, the manufacturing steps may occur in a different order that that which is noted in the Figures, and certain additional manufacturing steps may be implemented between the steps noted in the Figures. Moreover, any of the layered structures depicted in the Figures may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain junctions and uses electrons as the current carriers. The pFET includes p-doped source and drain junctions and uses holes as the current carriers. Complementary metal oxide semiconductor (CMOS) is a technology that uses complementary and symmetrical pairs of p-type and n-type MOSFETs to implement logic functions. As mentioned above, hole mobility on the pFET may have an impact on overall device performance.

The wafer footprint of an FET is related to the electrical conductivity of the channel material. If the channel material has a relatively high conductivity, the FET can be made with a correspondingly smaller wafer footprint. A known method of increasing channel conductivity and decreasing FET size is to form the channel as a nanostructure. For example, a so-called gate-all-around (GAA) nanosheet FET is a known architecture for providing a relatively small FET footprint by forming the channel region as a series of nanosheets. In a known GAA configuration, a nanosheet-based FET includes a source region, a drain region and stacked nanosheet channels between the source and drain regions. Semiconductor nanosheet FET devices typically include one or more suspended nanosheets that serve as the channel. A gate surrounds the stacked nanosheet channels and regulates electron flow through the nanosheet channels between the source and drain regions. GAA nanosheet FETs are fabricated by forming alternating layers of channel nanosheets and sacrificial nanosheets. The sacrificial nanosheets are released from the channel nanosheets before the FET device is finalized. For n-type FETs, the channel nanosheets are typically silicon (Si) and the sacrificial nanosheets are typically silicon germanium (SiGe). For p-type FETs, the channel nanosheets can be SiGe and the sacrificial nanosheets can be Si. In some implementations, the channel nanosheet of a p-type FET can be SiGe or Si, and the sacrificial nanosheets can be Si or SiGe. Forming the GAA nanosheets from alternating layers of channel nanosheets formed from a first type of semiconductor material (e.g., Si for n-type FETs, and SiGe for p-type FETs) and sacrificial nanosheets formed from a second type of semiconductor material (e.g., SiGe for n-type FETs, and Si for p-type FETs) provides superior channel electrostatics control, which is necessary for continuously scaling gate lengths down to seven (7) nanometer CMOS technology and below.

In certain nanosheet FET devices where an nFET device is formed on top of a pFET device, for the pFET the threshold voltage (Vt) may increase. Also, when a thickness of a TiN layer increases, pVt may be reduced. Therefore, there is a Vt difference between a top surface of the top channel region (e.g., a silicon layer of the nFET stack) of the nFET stack and the bottom surface of the top channel region (i.e., a space between adjacent channel regions in the nFET stack). In certain examples, the Vt difference between these top and bottom surfaces of the top channel region may be about 100 mV or more, where the top surface generally has a higher Vt than the bottom surface. This nonuniformity in Vt may lead to certain reductions in device performance. Therefore, it may be desirable to manufacture nanosheet FET structures that can address this nonuniformity in Vt around the channel regions of the nanosheet FET stacks.

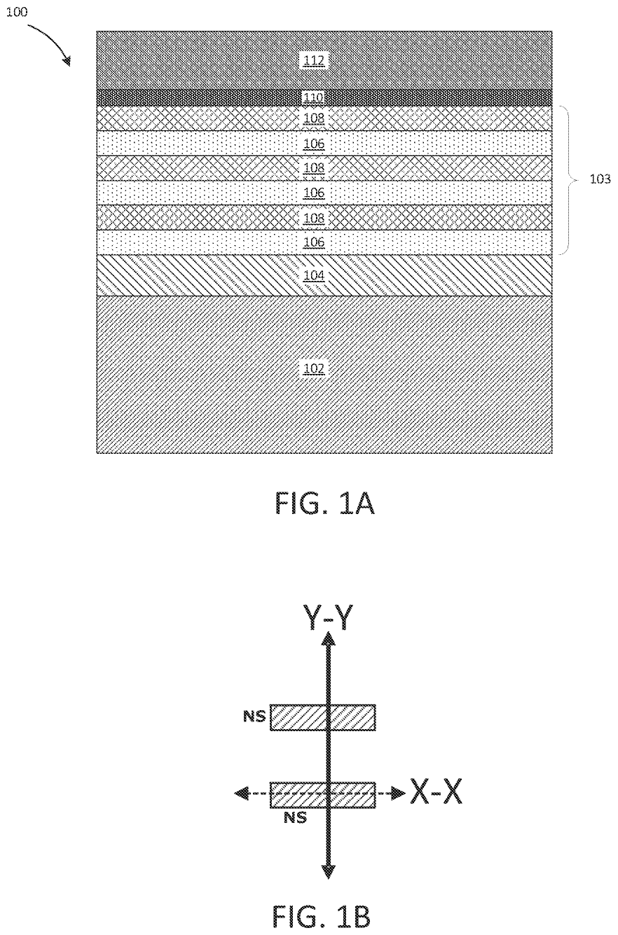

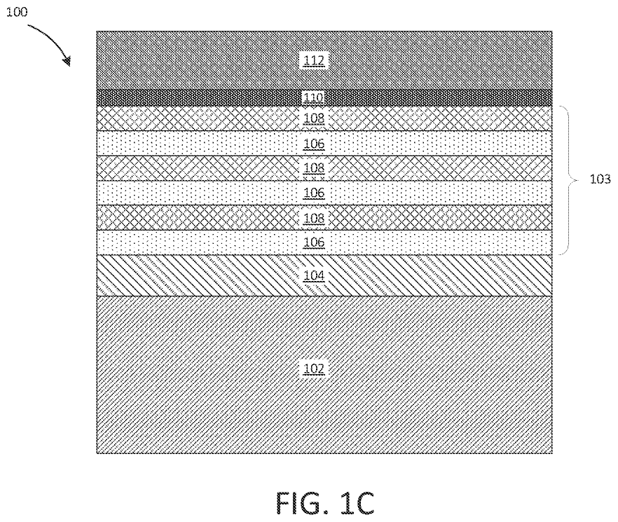

Referring now to the drawings in which like numerals represent the same or similar elements and initially to FIG. 1A, this figure depicts a cross-sectional view of a semiconductor device 100 at an intermediate stage of the manufacturing process, according to embodiments. The semiconductor device 100 may be formed over a substrate (not shown). The substrate may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon (Si) is the predominantly used semiconductor material in wafer fabrication, alternative semiconductor materials can be employed, such as, but not limited to, gallium arsenide, gallium nitride, cadmium telluride, zinc selenide, and III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements. Although not depicted in the present figures, the substrate may also be a semiconductor on insulator (SOI) substrate. The substrate may be comprised of any other suitable material(s) that those listed above.

As shown in FIG. 1A, after initial fabrication processing, a bottom transistor 102 is formed on the substrate. A bonding oxide layer 104 is formed on the bottom transistor 102. The bonding oxide may be any suitable oxide material and it may isolate the nanosheet stack 103 from the bottom transistor 102. In certain examples, the bottom transistor generically represents an nFET portion of a stacked FET device, and this is shown as a single layer for the sake of simplicity and for ease of understanding. The nanosheet stack 103 and related layers represent a pFET portion of a stacked FET device that is formed on the nFET portion (i.e., the bottom transistor 102). Thus, in various example embodiments, a bottom FET (i.e., bottom transistor 102) is formed, a bonding oxide layer 104 is deposited over the bottom FET, and then the top FET (i.e., nanosheet stack 103) is formed over the bonding oxide layer 104. The bottom FET includes bottom S/D epi regions, and the top FET includes top S/D epi regions. The bonding oxide layer 104 thus separates the bottom FET from the top FET. Stated differently, the bonding oxide layer 104 bonds the bottom FET to the top FET.

As shown in FIGS. 1A and 1C, a multi-layer nanosheet stack 103 is formed on the BDI layer 104. The nanosheet stack 103 includes a sacrificial layer 106, followed by the formation of an active semiconductor layer 108. In certain examples, the first one of the sacrificial layers 106 is initially formed directly on an upper surface of the bonding oxide layer 104. In other examples, certain layers may be formed between the upper surface of the bonding oxide layer 104 and the first one of the sacrificial layers 106. In an example, the sacrificial layer 106 is composed of silicon-germanium (e.g., SiGe35, or more generally, where the Ge ranges from about 25-40%). Next, an active semiconductor layer 108 is formed on an upper surface of the first one of the sacrificial layers 106. In an example, the active semiconductor layer 108 is composed of silicon. Several additional layers of the sacrificial layer 106 and the active semiconductor layer 108 are alternately formed. In the example illustrated in FIGS. 1A and 1C, there are a total of three sacrificial layers 106 and three active semiconductor layers 108 that are alternately formed to form the nanosheet stack 103. However, it should be appreciated that any suitable number of alternating layers may be formed. Although it is specifically contemplated that the sacrificial layers 106 can be formed from silicon germanium and that the active semiconductor layers 108 can be formed from silicon, it should be understood that any appropriate materials can be used instead, as long as the two semiconductor materials have etch selectivity with respect to one another. As used herein, the term “selective” in reference to a material removal process denotes that the rate of material removal for a first material is greater than the rate of removal for at least another material of the structure to which the material removal process is being applied. The alternating semiconductor materials can be deposited by any appropriate mechanism. It is specifically contemplated that the first and second semiconductor materials (i.e., of the sacrificial layers 106 and the active semiconductor layers 108) can be epitaxially grown from one another, but alternate deposition processes, such as chemical vapor deposition (CVD), physical vapor deposition (PVD), atomic layer deposition (ALD), or gas cluster ion beam (GCIB) deposition, are also contemplated.

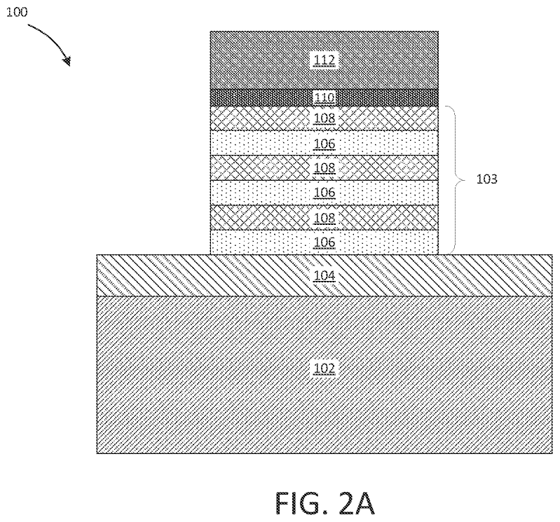

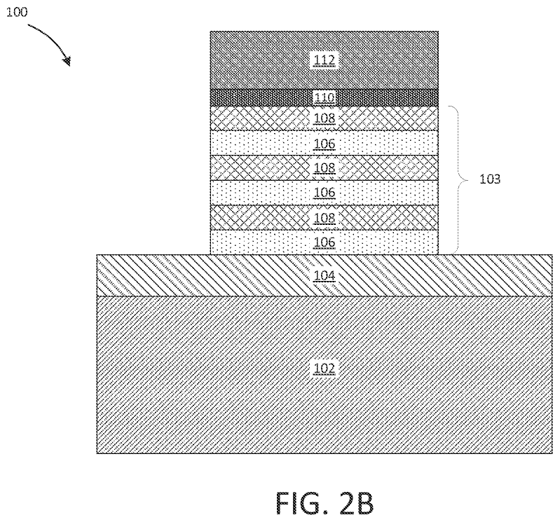

In certain embodiments, the sacrificial layers 106 have a vertical thickness ranging, for example, from approximately 3 nm to approximately 20 nm. In certain embodiments, the active semiconductor layers 108 have a vertical thickness ranging, for example, from approximately 3 nm to approximately 10 nm. Although six total layers are illustrated in FIG. 2, it should be appreciated that the nanosheet stack 103 can include any suitable number of layers. Although the range of 3-20 nm is cited as an example range of thickness, other thickness of these layers may be used. In certain examples, certain of the sacrificial layers 106 or the active semiconductor layers 108 may have different thicknesses relative to one another. Therefore, multiple epitaxial growth processes can be performed to form the alternating sacrificial layers 106 and the active semiconductor layers 108.

In certain embodiments, it may be desirable to have a small vertical spacing (VSP) between adjacent nanosheet layers in a stack of nanosheets to reduce the parasitic capacitance and to improve circuit speed. For example, the VSP (the distance between the bottom surface of a first nanosheet layer and the top surface of an adjacent second nanosheet layer) may range from 5 nm to 15 nm. However, the VSP must be of a sufficient value to accommodate the gate stack that will be formed in the spaces created by later removal of the sacrificial layers 106.

As also shown in FIGS. 1A and 1C, a capping layer 110 is formed on the uppermost active semiconductor layer 108. The capping layer 110 may be a thin SiGe layer having a lower Ge content than that of the sacrificial layers 106. In one example, the capping layer is a thing SiGe having a Ge content of about 10% or less. In certain examples, the lower Ge content capping layer 110 lowers the Vt of the topmost channel region. As discussed above, in related FET devices, there may be nonuniformity in the Vt profile around the topmost channel region. The present embodiments address this nonuniformity by providing the lower Ge content capping layer 110 on the top side of the nanosheet stack 103. As also shown in FIGS. 1A and 1C, a hardmask 112 is provided on top of the capping layer 110. The hardmask 112 may be comprised of any suitable material(s) known to one of skill in the art, and it may be used for patterning the nanosheet stack 103 in subsequent manufacturing operations.

Referring now to FIG. 2A, this figure shows a cross-sectional view of the semiconductor device 100 of FIG. 1A taken along the line Y-Y of FIG. 1B, according to embodiments. As shown in FIGS. 2A and 2B (a cross-sectional view of the semiconductor device FIG. 1C after additional fabrication operations and taken along the line X-X of FIG. 1B), the hardmask 112 is patterned and used to perform the nanosheet patterning process. In the nanosheet patterning process, any suitable material removal process (e.g., reactive ion etching or RIE) may be used to remove the material of the capping layer 110 and the various layers of the nanosheet stack 103 down to the level of the bonding oxide layer 104.

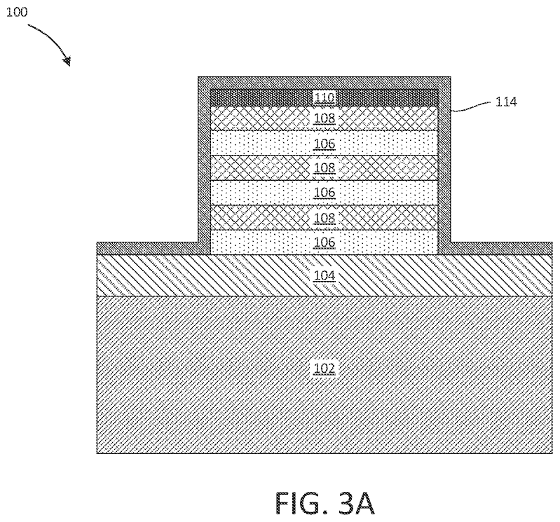

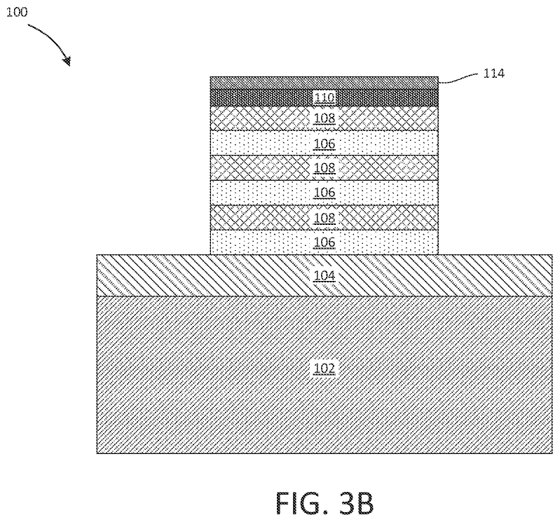

Referring now to FIG. 3A, this figure shows a cross-sectional view of the semiconductor device of FIG. 2A after additional manufacturing operations and taken along the line Y-Y of FIG. 1B, according to embodiments. As shown in FIG. 3A and FIG. 3B (a cross-sectional view of the semiconductor device FIG. 2B after additional fabrication operations and taken along the line X-X of FIG. 1B), following the patterning process to the nanosheet stack 103 (e.g., all of the sacrificial layers 106 and semiconductor layers 108) the hardmask 112 is removed and then a sacrificial oxide layer 114 is formed over the entire nanosheet stack 103 and to cover the bonding oxide layer 104. As shown in FIG. 3B, certain portions of the sacrificial oxide layer 114 are removed when viewed along the X-X cutline. As shown in FIG. 3B, the removal of these portions of the sacrificial oxide layer 114 expose the side walls of the nanosheet stack 103 and the bonding oxide layer 104. It should be appreciated that the sacrificial oxide layer 114 may include one or more suitable oxide materials such as, for example, SiO₂.

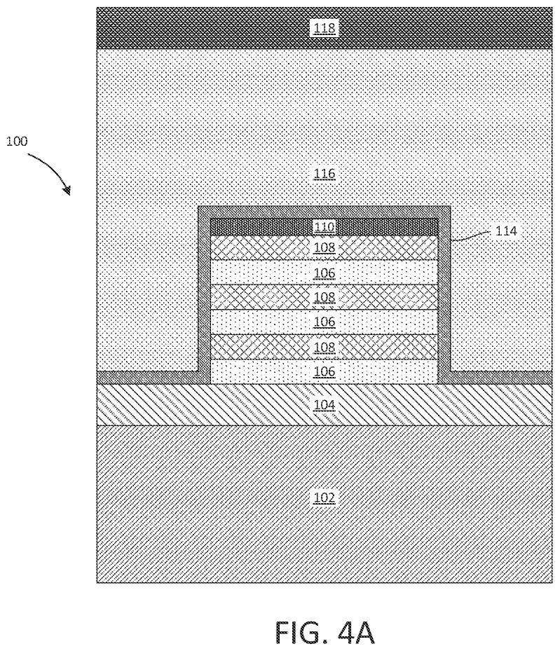

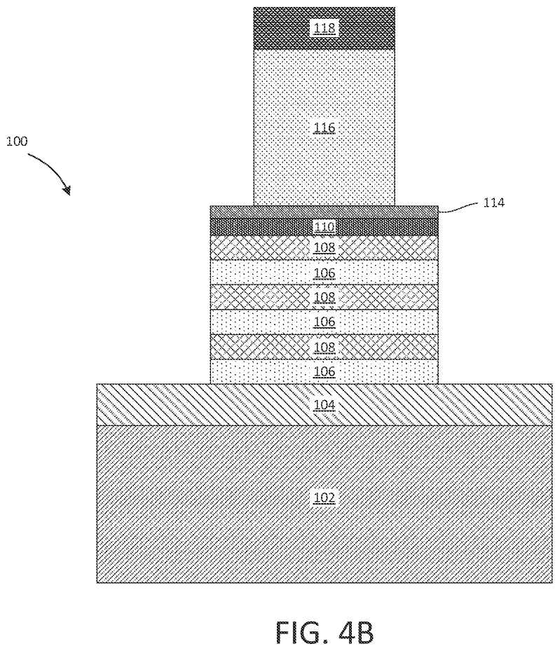

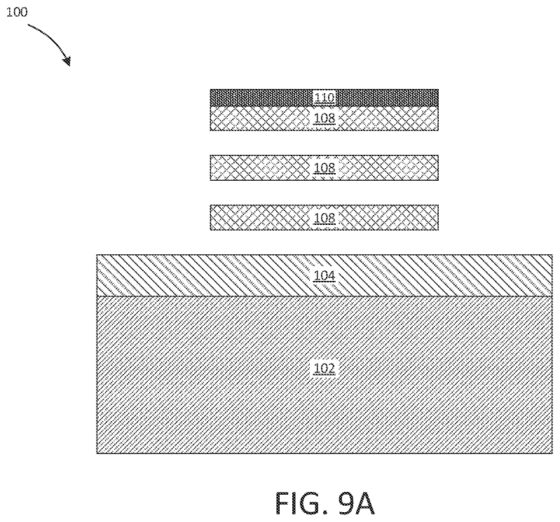

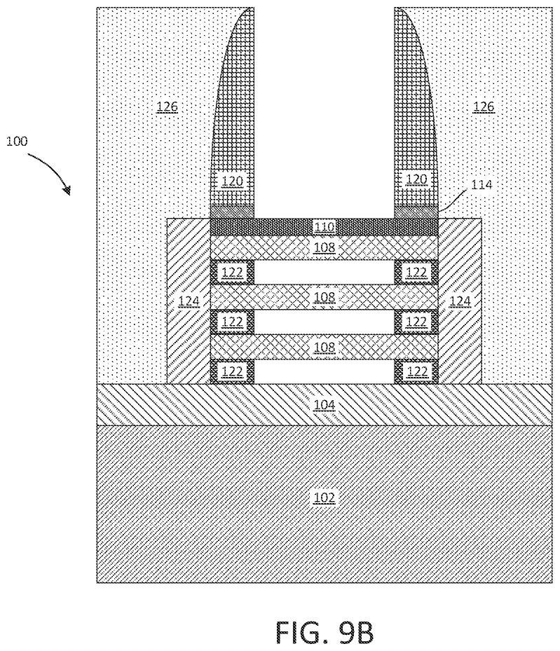

Referring now to FIG. 4A, this figure is a cross-sectional view of the semiconductor device of FIG. 3A after additional manufacturing operations and taken along the line Y-Y of FIG. 1B, according to embodiments. As shown in FIGS. 4A and 4B (a cross-sectional view of the semiconductor device FIG. 3B after additional fabrication operations and taken along the line X-X of FIG. 1B), a dummy gate 116 (or sacrificial gate) is formed on the sacrificial oxide layer 114 by any suitable deposition and/or patterning processes known to one of skill in the art. In one example, the dummy gate 116 is formed by depositing a thin SiO₂ dummy gate oxide layer (or sacrificial oxide layer 114), followed by depositing a layer of amorphous silicon (a-Si) as the dummy gate 116. The dummy gate 116 may be composed of polycrystalline silicon (poly silicon), amorphous silicon, and/or an oxide, such as, SiO₂. A gate hardmask 118 is also formed on a top sides of the dummy gate 116. The gate hardmask 118 is formed for subsequent nanosheet patterning. The gate hardmask 118 can be composed of various nitride materials including, but not limited to, a nitride, an oxide, silicon nitride (SiN), and/or a combination of a nitride material and an oxide material. In certain embodiments, as shown in FIG. 4A, the dummy gate 116 extends into and out of the page to wrap around the edges of the nanosheet stack 103, and the subsequent removal of the dummy gate 116 (see, FIGS. 9A and 9B) allows an access point for later removal of the sacrificial layers 106. In certain examples, gate patterning may be performed by first patterning the gate hardmask 118 and then using the patterned gate hardmask 118 to etch the dummy gates 116, as shown in FIG. 4B.

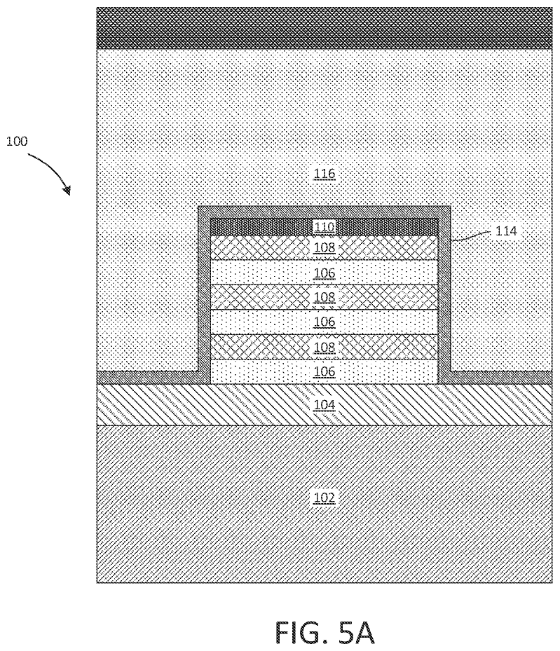

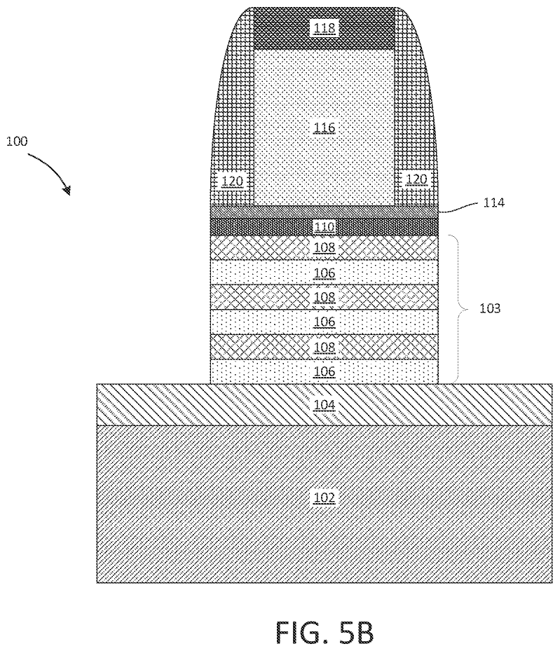

Referring now to FIG. 5A, this figure shows a cross-sectional view of the semiconductor device of FIG. 4A after additional manufacturing operations and taken along the line Y-Y of FIG. 1B, according to embodiments. As shown in FIG. 5B (a cross-sectional view of the semiconductor device FIG. 4B after additional fabrication operations and taken along the line X-X of FIG. 1B), a spacer 120 (or spacer layer) is formed on the sidewalls of the patterned dummy gate 116 and the gate hardmask 118. In certain examples, the spacer 120 is formed to cover the sacrificial oxide layer 114 and extends out to the sidewalls of the nanosheet stack 103. There are no changes to the cross-sectional view of FIG. 5A relative to FIG. 4A.

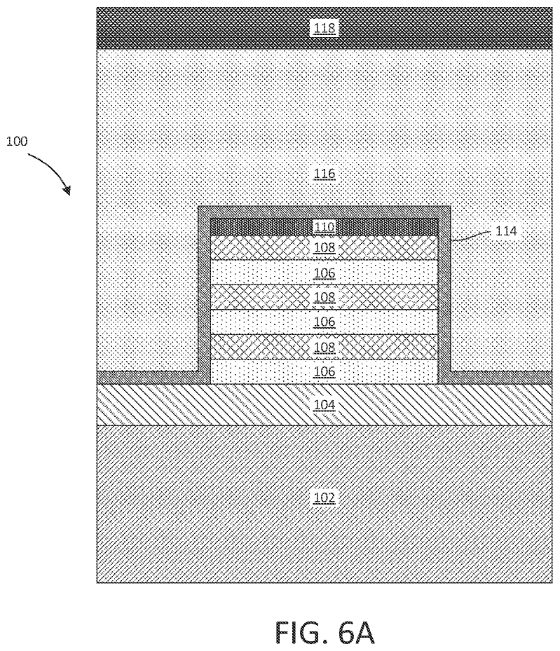

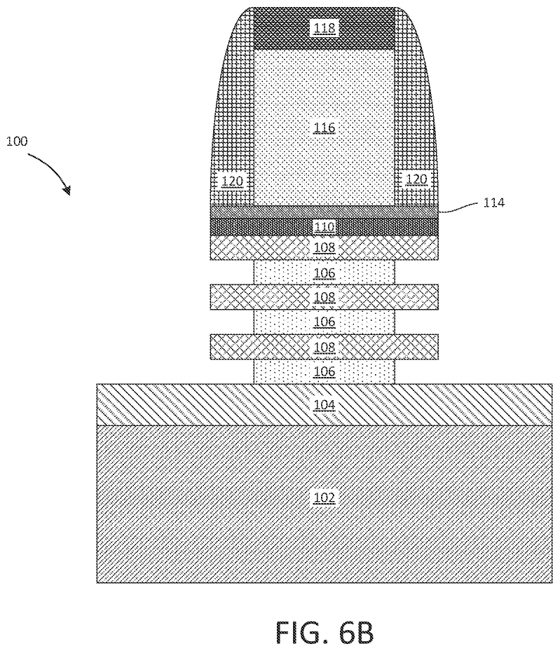

Referring now to FIG. 6A, this figure is a cross-sectional view of the semiconductor device of FIG. 5A after additional manufacturing operations and taken along the line Y-Y of FIG. 1B, according to embodiments. As shown in FIG. 6B (a cross-sectional view of the semiconductor device FIG. 5B after additional fabrication operations and taken along the line X-X of FIG. 1B), the semiconductor device 100 is subjected to a directional reactive ion etch (RIE) process, which is capable of removing portions of the sacrificial layers 106 not covered by the dummy gate 116 (and the dummy gate hardmask 118) and the spacer 120. The RIE can use a boron-based chemistry or a chlorine-based chemistry, for example, which selectively recesses the exposed portions sacrificial layers 106 without significantly removing the active semiconductor layers 108. There are no changes to the cross-sectional view of FIG. 6A relative to FIG. 5A. Thus, portions of the sacrificial layers 106 are recessed in an inward direction (i.e., an inner spacer indentation process) so that the processed widths of the sacrificial layers 106 are less than widths of the active semiconductor layers 108.

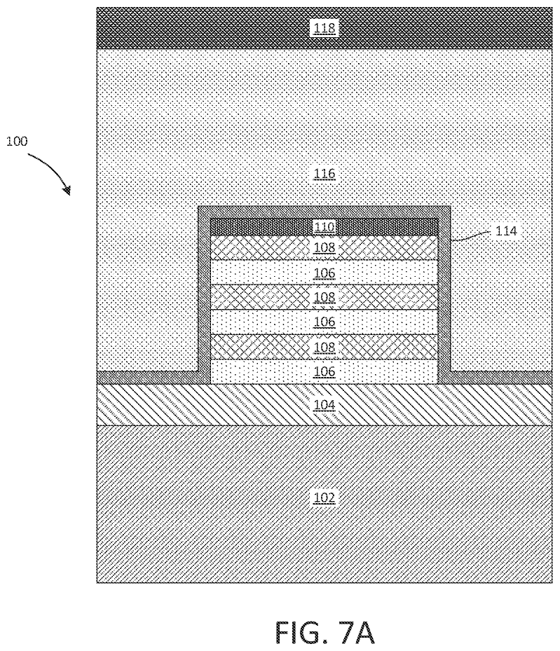

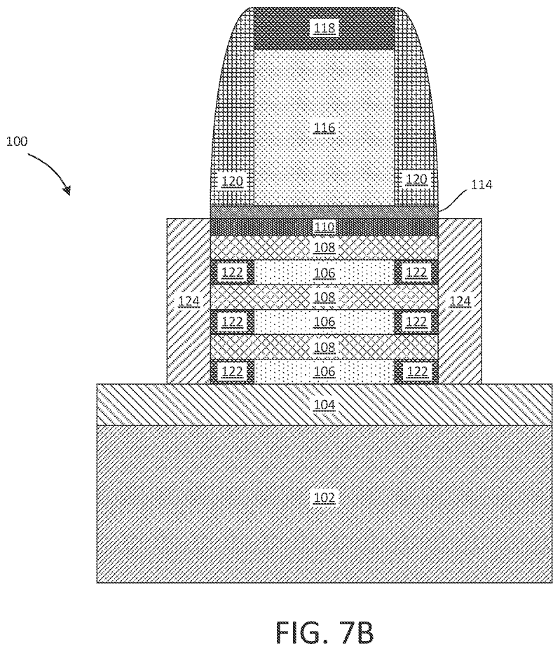

Referring now to FIG. 7A, this figure is a cross-sectional view of the semiconductor device of FIG. 6A after additional manufacturing operations and taken along the line Y-Y of FIG. 1B, according to embodiments. As shown specifically in FIG. 7B (a cross-sectional view of the semiconductor device FIG. 6B after additional fabrication operations and taken along the line X-X of FIG. 1B), inner spacers 122 are added in the recesses that were previously formed into the sacrificial layers 106. In certain embodiments, after the formation of the inner spacers 122, an isotropic etch process is performed to create outer vertical edges to the inner spacers 122 that align with outer vertical edges of the active semiconductor layers 108. In certain embodiments, the material of the inner spacer 122 is a dielectric material such as SiN, SiO, SiBCN, SiOCN, SiCO, etc. There are no changes to the cross-sectional view of FIG. 7A relative to FIG. 6A.

As also shown in FIG. 7B, an epitaxial layer 124 is formed to cover the sidewalls of the nanosheet stack 103. The epitaxial layer 124 forms a junction in the semiconductor device 100. In certain embodiments, the epitaxial layer 124 may be the source/drain of the p-type GAA FET. Then, the epitaxial layer 124 (e.g., pFET layer) is deposited by an epitaxial growth method up to at least the level of the top of the nanosheet stack 103. In certain embodiments, the material of the epitaxial layer 124 is SiGeB. However, it should be appreciated that any other suitable materials may be used.

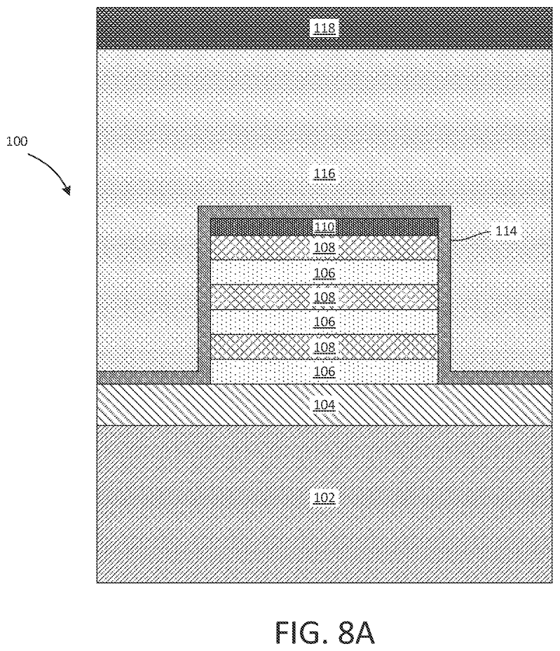

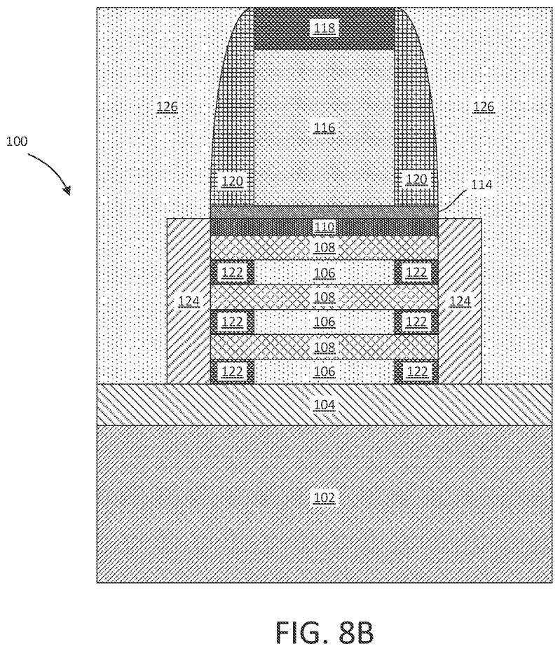

Referring now to FIG. 8A, this figure is a cross-sectional view of the semiconductor device of FIG. 7A after additional manufacturing operations and taken along the line Y-Y of FIG. 1B, according to embodiments. As shown specifically in FIG. 8B (a cross-sectional view of the semiconductor device FIG. 7B after additional fabrication operations and taken along the line X-X of FIG. 1B), an interlayer dielectric (ILD) layer 126 is formed around the nanosheet stack 103 up to the level of the top of the gate hardmask 118. In certain examples, a planarization process such as CMP may be performed to create a planar surface for the semiconductor device 100. There are no changes to the cross-sectional view of FIG. 8A relative to FIG. 7A. The ILD layer 126 can be any suitable material, such as, for example, porous silicates, carbon doped oxides, silicon dioxides, silicon nitrides, silicon oxynitrides, or other dielectric materials. Any known manner of forming the ILD layer 126 can be utilized. The ILD layer 126 can be formed using, for example, CVD, PECVD, ALD, flowable CVD, spin-on dielectrics, or PVD.

Referring now to FIG. 9A, this figure is a cross-sectional view of the semiconductor device of FIG. 8A after additional manufacturing operations and taken along the line Y-Y of FIG. 1B, according to embodiments. As shown in FIGS. 9A and 9B (a cross-sectional view of the semiconductor device FIG. 8B after additional fabrication operations and taken along the line X-X of FIG. 1B), following the formation of the ILD layer 126, a selective removal of the dummy gate hardmask 118, the dummy gate 116, the sacrificial oxide layer 114, and the sacrificial layers 106 (i.e., the SiGe suspensions) is performed. As shown in FIGS. 9A and 9B, the dummy gate 116 is removed by any suitable material removal process known to one of skill in the art. For example, such removal may be accomplished by an etching process which may include a dry etching process such as, for example, reactive ion etching, plasma etching, ion etching or laser ablation. The etching can further include a wet chemical etching process in which one or more chemical etchants are used to remove portions of the blanket layers that are not protected by the patterned photoresist. Then, the sacrificial layers 106 are removed (or released). Thus, as shown in FIGS. 9A and 9B, there are void spaces between the active semiconductor layers 108 due to the removal of the sacrificial layers 106. It should be appreciated that during the removal of the dummy gate hardmask 118, the dummy gate 116, the sacrificial oxide layer 114, and the sacrificial layers 106, appropriate etchants are used that do not significantly remove material of the capping layer 110 (e.g., the low Ge content SiGe layer). The dry and wet etching processes can have etching parameters that can be tuned, such as etchants used, etching temperature, etching solution concentration, etching pressure, source power, RF bias voltage, RF bias power, etchant flow rate, and other suitable parameters. Dry etching processes can include a biased plasma etching process that uses a chlorine-based chemistry. Other dry etchant gasses can include Tetrafluoromethane (CF4), nitrogen trifluoride (NF3), sulfur hexafluoride (SF6), and helium (He), and Chlorine trifluoride (C1F3). Dry etching can also be performed anisotropically using such mechanisms as DRIE (deep reactive-ion etching). Chemical vapor etching can be used as a selective etching method, and the etching gas can include hydrogen chloride (HCl), Tetrafluoromethane (CF4), and gas mixture with hydrogen (H2). Chemical vapor etching can be performed by CVD with suitable pressure and temperature.

Thus, as shown in FIG. 9A, the active semiconductor material layer 108 remains, and a topmost channel region of the nanosheet stack 103 still retains the capping layer 110. This has the effect of altering (e.g., lowering) the Vt for topmost channel region, and improving the Vt uniformity over the entire nanosheet stack 103 to improve the performance of the semiconductor device 100.

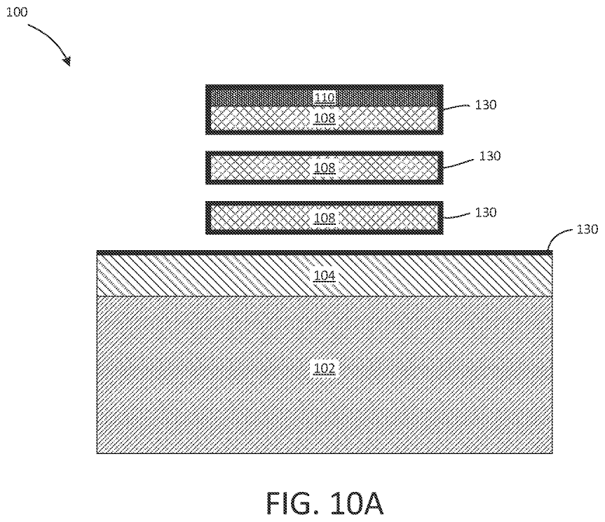

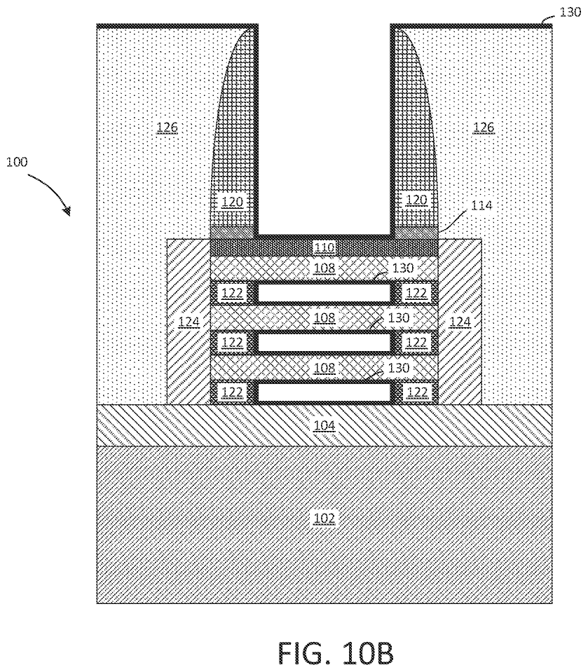

Referring now to FIG. 10A, this figure is a cross-sectional view of the semiconductor device of FIG. 9A after additional manufacturing operations and taken along the line Y-Y of FIG. 9B, according to embodiments. As shown in FIG. 10B (a cross-sectional view of the semiconductor device FIG. 9B after additional fabrication operations and taken along the line X-X of FIG. 1B), following the removal of the sacrificial layers 106 and the dummy gate 116, an interfacial layer 130 is formed on the interior surfaces of the spacer 120 and the interior surfaces of the active semiconductor layers 108 and the inner spacers 122. Then, a high-K layer (not shown) is formed to cover all of the surfaces of exposed surfaces of the interfacial layer 130. The high-K layer can be deposited by any suitable techniques, such as ALD, CVD, metal-organic CVD (MOCVD), physical vapor deposition (PVD), thermal oxidation, combinations thereof, or other suitable techniques. The high-K layer is a material with a higher dielectric constant than that of SiO₂, and can include, e.g., LaO, AlO, ZrO, TiO, Ta₂O₅, Y₂O₃, SrTiO₃(STO), BaTiO₃ (BTO), BaZrO, HfZrO, HfLaO, HfSiO, LaSiO, AlSiO, HfTaO, HfSiO, (Ba,Sr)TiO₃ (BST), Al₂O₃, Si₃N₄, oxynitrides (SiON), or other suitable materials. The high-K layer can include a single layer or multiple layers, such as metal layer, liner layer, wetting layer, and adhesion layer. In other embodiments, the high-K layer can include, e.g., Ti, Ag, Al, TiAlN, TaC, TaCN, TaSiN, Mn, Zr, TiN, TaN, Ru, Mo, Al, WN, Cu, W, or any suitable materials.

Referring again to FIG. 10A, the interfacial layer 130 is formed on the exterior surfaces of the active semiconductor layer 130. Specifically, with regard to the topmost channel region (i.e., the uppermost layer of the nanosheet stack 103 that includes the active semiconductor layer 108 and the capping layer 110), the interfacial layer 130 covers the exterior surfaces of the combined active semiconductor layer 108 and the capping layer 110.

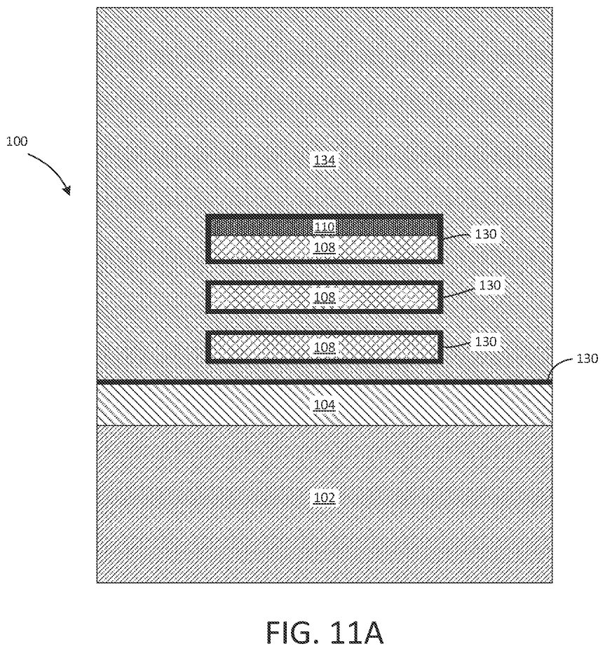

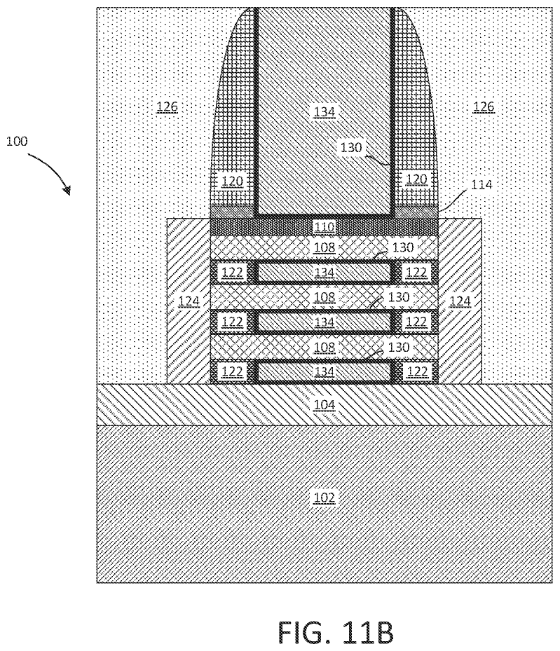

Referring now to FIG. 11A, this figure is a cross-sectional view of the semiconductor device of FIG. 10A after additional manufacturing operations and taken along the line Y-Y of FIG. 1B, according to embodiments. As shown in FIG. 11B (a cross-sectional view of the semiconductor device FIG. 10B after additional fabrication operations and taken along the line X-X of FIG. 1B), the previously removed dummy gate 116 is replaced with a work function metal (WFM) layer 134 (or gate layer). In certain embodiments, the WFM layer 134 may be the gate of the p-type GAA FET. The WFM layer 134 can be comprised of metals, such as, e.g., copper (Cu), cobalt (Co), aluminum (Al), platinum (Pt), gold (Au), tungsten (W), titanium (Ti), nitride (N) or any combination thereof. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. In various exemplary embodiments, the height of the WFM layer 134 can be reduced by chemical-mechanical polishing (CMP) and/or etching. Therefore, the planarization process can be provided by CMP. Other planarization process can include grinding and polishing. In general, the work function metal (WFM) layer 134 sets the threshold voltage (Vt) of the device, a high-K gate dielectric material separating the WFM from the nanosheets, and other metals that may be desired to further fine tune the effective work function (eWF) and/or to achieve a desired resistance value associated with current flow through the gate stack in the direction parallel to the plane of the nanosheets. Also, as described above, the capping layer 110 including the low Ge content SiGe (e.g., about Ge % 10 or less) further tunes the Vt of the semiconductor device 100 and creates a more uniform profile to the entire nanosheet stack 103.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a semiconductor substrate;
a pFET transistor formed on the semiconductor substrate;
wherein the pFET transistor includes a plurality of channel regions, and an uppermost channel region of the pFET transistor includes an uppermost active semiconductor layer and a capping layer formed on the uppermost active semiconductor layer.

2. The semiconductor device of claim 1, wherein the capping layer comprises SiGe having 5-15% Ge content.

3. The semiconductor device according to claim 1, wherein the capping layer has a thickness of about 2-3 nm.

4. The semiconductor device according to claim 1, further comprising an interfacial layer that is formed around the capping layer and uppermost active semiconductor layer.

5. The semiconductor device according to claim 4, further comprising a high-K layer formed on the interfacial layer.

6. The semiconductor device according to claim 1, wherein the pFET transistor is a nanosheet structure including at least two stacked active semiconductor layers surrounded by a WFM layer.

7. The semiconductor device according to claim 1, further comprising a sacrificial oxide layer formed on the capping layer.

8. The semiconductor device according to claim 7, further comprising a spacer layer formed on the sacrificial oxide layer.

9. The semiconductor device of claim 1, wherein the semiconductor substrate includes an nFET transistor.

10. The semiconductor device of claim 9, further comprising a bonding oxide layer formed on the nFET transistor, wherein the pFET transistor is formed on the bonding oxide layer.

11. A method of forming a semiconductor device, the method comprising:
forming a pFET transistor on a semiconductor substrate;
wherein the pFET transistor includes a plurality of channel regions, and an uppermost channel region of the pFET transistor includes an uppermost active semiconductor layer and a capping layer formed on the uppermost active semiconductor layer.

12. The method of claim 11, wherein the capping layer comprises SiGe having 5-15% Ge content.

13. The method according to claim 11, wherein the capping layer has a thickness of about 2-3 nm.

14. The method according to claim 11, further comprising forming an interfacial layer that around the capping layer and uppermost active semiconductor layer.

15. The method according to claim 14, further comprising forming a high-K layer on the interfacial layer.

16. The method according to claim 11, wherein the pFET transistor is a nanosheet structure including at least two stacked active semiconductor layers surrounded by a WFM layer.

17. The method according to claim 11, further comprising forming a sacrificial oxide layer on the capping layer.

18. The method according to claim 17, further comprising forming a spacer layer on the sacrificial oxide layer.

19. The method of claim 11, wherein the semiconductor substrate includes an nFET transistor.

20. The method of claim 19, further comprising forming a bonding oxide layer on the nFET transistor, wherein the pFET transistor is formed on the bonding oxide layer.
